(19) United States
(12) Patent Application Publication
(10) Pub. No.: US 2015/0240103 A1
(43) Pub. Date: Aug. 27, 2015

(54) COMPOSITIONS FOR HIGH SPEED PRINTING OF CONDUCTIVE MATERIALS FOR ELECTRONIC CIRCUITRY TYPE APPLICATIONS AND METHODS RELATING THERETO

(71) Applicant: E I DU PONT DE NEMOURS AND COMPANY, Wilmington, DE (US)

(72) Inventors: WILLIAM BROWN FARNHAM, Hockessin, DE (US); Dave Hui, Bristol (GB)

(21) Appl. No.: 14/610,743

(22) Filed: Jan. 30, 2015

Related U.S. Application Data
(60) Provisional application No. 61/944,088, filed on Feb. 25, 2014.

(51) Int. Cl. C09D 11/52; H05K 3/02; C09D 11/38

(52) U.S. Cl. CPC C09D 11/52; C09D 11/38; H05K 3/02

(57) ABSTRACT

The present invention is directed to compositions for high speed printing of conductive materials for electronic circuitry type applications. These compositions are dispersions having a continuous (e.g., solvent) phase and a discontinuous phase. The discontinuous phase includes a plurality of nanoparticles stabilized with a thermally decomposable stabilizer. The thermally decomposable stabilizer is an Φ-b-θ-Y block co-polymer or oligomer where: i. Φ is a polymeric block or series of polymeric blocks that swell and suspend in the continuous phase; ii. b indicates a covalent bond between Φ and θ; iii. θ comprises at least one moiety from the group consisting of tertiary amines, electron rich aromatics, acrylates, methacrylates and combinations thereof; and iv. Y is a dithioester, a xanthate, a dithiocarbamate, a trithiocarbonate or a combination thereof.

### FIELD OF THE INVENTION

The field of the invention relates generally to dispersions of conductive nanoparticles that can be destabilized with the application of relatively low amounts of heat energy or with relatively low amounts of electromagnetic (e.g., ultra violet or microwave) radiation to purposefully cause the nanoparticles to fall out of suspension and form desired conductive nanoparticle agglomerate features. More specifically, the compositions of the present invention are useful for high speed printing of conductive material for electronic circuitry type applications or the like.

### BACKGROUND OF THE INVENTION

A need exists to inexpensively fabricate conductive circuitry features on circuit boards and other substrates. High vacuum techniques are commonly used, such as, sputtering, chemical vapor deposition (CVD), and atomic layer deposition (ALD). Such techniques are generally able to achieve high-quality conductor deposition, but tend to suffer from low deposition speeds, high cost, limited scalability, and/or high processing temperatures.

U.S. Patent Application Number 2009/0181183A1 to Yuming Li, et al. is directed to stabilized metal nanoparticles and methods for depositing conductive features by intentionally destabilizing the metal nanoparticle suspension. However, a need exists for improvements to such metal nanoparticle suspensions, particularly for more reliable stability during transportation and storage prior to use, and a faster, more accurate, and more efficient destabilization mechanism to enable high speed production techniques, such as, reel to reel embedding processes that may include lamination, curing and delamination over the course of just a few seconds, or less.

U.S. Pat. No. 7,138,468 to McCormick, et al., is directed to a method of generating thio-functionalized transition metal nanoparticles and surfaces modified by (co)polymers synthesized by the RAFT (Reverse Additions-fragmentation chain Transfer synthesis) methods. The methods of the McCormick patent include the steps of forming a (co)polymer in aqueous solution using the RAFT methodology and forming a colloidal dispersion in a way that minimizes aggregation.

### SUMMARY OF THE INVENTION

The present invention is directed to compositions for high speed printing of conductive materials for electronic circuitry type applications. These compositions are dispersions having a continuous phase and a discontinuous phase. The discontinuous phase comprises a plurality of nanoparticles stabilized with a cleavable stabilizer.

The nanoparticles comprise: i. at least 50 weight percent silver at the particle surface; ii. an aspect ratio of from 1-3:1; and iii. a particle size of 1 to 100 nanometers. The thermally decomposable stabilizer is an Φ-b-θ-Y block co-polymer or oligomer by Reversible Addition-Fragmentation chain Transfer (RAFT) synthesis. The block copolymer or oligomer is applied to the nanoparticles or a nanoparticle precursor in the presence of: i. a reducing agent sufficient to cause a reduction within Y; ii. an increase in pH sufficient to cause hydrolysis within Y; Hi, a weak surfactant at the silver surface; or iv. a combination of two or more of i., ii. and iii.

Φ is a polymeric block or series of polymeric blocks that swell and suspend in the continuous phase. In an embodiment, the polymeric block or series of polymeric blocks may be partially soluble in the continuous phase. In a further embodiment, the polymeric block or series of polymeric blocks may be completely soluble in the continuous phase. Φ has a weight average molecular weight in a range from 1000 to 150,000. b indicates a covalent bond between Φ and θ. θ comprises at least one acrylate, methacrylate or combinations thereof with pendant moieties from the group consisting of tertiary amines, and electron rich aromatics. θ is from 10, 15, 20, 25, or 30 weight percent to 35, 40, 45, 50, 55, or 60 weight percent of the thermally decomposable stabilizer. Electron rich aromatics are aromatics with electron donating substituents that donate electron(s) to the ring, making the ring electron rich, e.g., aniline (amino benzene), furan, thiophene, pyrrole, oxazole, imidazole, halogenated aromatics, and the like.

Y is a dithioester, a xanthate, a dithiocarbamate, a trithiocarbonate or a combination thereof. Upon heating the discontinuous phase to a temperature of 110, 120, 125, 130, 135, 140, 145, 150, 155, 160, 165, 170, 175 or 180° C., for a time within the range of 0.01, 0.03, 0.05, 0.08, 0.1, 0.15, 0.2, 0.3, 0.4, 0.5, 0.8, 1, 2, 3, 4 to 5 minutes, sufficient bond cleavage occurs within Y or between Y and 8 to cause at least 50, 60, 70, 80, 90, 95, or 100 weight percent of the nanoparticles to fall out of suspension and agglomerate. The resulting agglomerate generally has a sufficiently low resistance to be a useful conductor in many conventional applications, when applied to a circuit substrate. The agglomerated nanoparticles are generally sinterable at a temperature in a range between and optionally including any two of the following: 100, 110, 120,125, 130, 135, 140,150, 160,170, 180, 190, 200, 250 and 300° C. to further reduce resistance.

In one embodiment, the continuous phase comprises a solvent selected from the group consisting of water, alcohols (including in particular: methanol, ethanol, propanol, isopropanol, butanol, pentanol, hexanol, heptanol, octanol, glycols, and the like), ethers (including in particular tetrahydrofuran), esters, substituted aliphatics and aromatics amides (including in particular N,N-dimethylformamide (DMF)), and combinations thereof. In one embodiment, the thermally decomposable stabilizer is in a range between and optionally including any two of the following: 0.01, 0.02, 0.05, 0.08, 1, 2, 3, 4, 5, 6, 7, 8, 9, 10, 11, 12, 13, 14 and 15 weight percent of the total weight of the discontinuous phase. In one embodiment, the continuous phase is less than 40, 45, 50, 55, 60, 65, or 70 wt % of the total weight of the continuous phase and discontinuous phase. In one embodiment, the dispersion also includes a surfactant to lower the interfacial tension between the continuous phase and discontinuous phase; depending upon the particular embodiment chosen, any one of a large number of surfactants are possible, including cationic, anionic, non-ionic or zwitterion surfactants such as, for example, xanthan gum or any natural gum or natural gum derivative surfactant.

The present invention is also directed to a method of printing a conductive feature. In accordance with this method, dispersion as described above is deposited onto a substrate. Thereafter or simultaneously, the discontinuous phase is heated to a temperature in a range between and including any two of the following: 100, 110, 120, 125, 130, 135, 140, 145, 150 and 160° C. for a period of time in a range between and optionally including any two of the following of 0.01, 0.05, 0.1, 0.5, 1, 2, 3, 5, 7, 8, 9, or 10 minutes to cause at least 30, 40, 50, 60, 70, 80, 90, 95 or 100 wt % of the nanoparticles to fall out of suspension to form a nanoparticle agglomerate. Thereafter at least a portion of the continuous phase is removed, and the nanoparticle agglomerate can optionally be heated to a temperature above 100, 110 or 120° C. to optionally further sinter the nanoparticle agglomerate, thereby lowering the resistivity of the nanoparticle agglomerate, in some instances, more than 5, 10, 15, 20, 25, 30, 40, of 50%.

### DEFINITIONS

“Chain transfer agents” (CTA) as used herein refer to those compounds useful in polymeric reactions having the ability to add monomer units to continue a polymerization process.

“Free-radical initiators” (initiators) as used herein refer to a species comprising any of the large number of organic compounds with a labile group which can be readily broken by heat or irradiation (UV, gamma, etc.) and have the ability to initiate free radical chain reactions.

“Monomer” as used herein means a polymerizable allylic, vinylic, or acrylic compound which may be anionic, cationic, non-ionic, or zwitterionic.

“Anionic copolymers” as used herein, refer to those (co)polymers which possess a net negative charge.

“Anionic monomer” as defined herein refers to a monomer which possesses a net negative charge. Representative examples of anionic monomers include metal salts of acrylic acid, sulfopropyl acrylate, methacrylate, or other water-soluble forms of these or other polymerizable carboxylic acids or sulphonic acids, and the like.

“Cationic (co)polymers”, as defined herein, refer to those (co)polymers which possess a net positive charge.

“Cationic monomers”, as defined herein, refer to those monomers which possess a net positive charge. Representative cationic monomers include the quaternary salts of dialkylaminoalkyl acrylates and methacrylates, N,N-diallydialkyl ammonium halides (such as DADMAC), N,N-dimethylaminoethylacrylate methyl chloride quaternary salt, and the like.

“Neutral” or “non-ionic (co)polymers”, as defined herein, refer to those (co)polymers which are electrically neutral and possess no net charge.

“Nonionic monomers” are defined herein to mean a monomer which is electrically neutral. Representative nonionic or neutral monomers are acrylamide, N-methylacrylamide, N,N-dimethyl(meth)acrylamide, N-methylolacrylamide, N-vinylformamide, and N,N-dimethylacrylamide, as well as hydrophilic monomers such as ethylene glycol methyacrylate, (meth)acrylates with poly(EO) or poly(PO) segments (where EO means ethylene oxide segments and PO means propylene oxide segments).

“Betaine”, as used herein, refers to a general class of salt compounds, especially zwitterionic compounds, and include polybetaines. Representative examples of betaines which can be used with the present invention include: N,N-dimethyl-N-acryloyloxyethyl-N-(3-sulfopropyl)-ammonium betaine, N,N-dimethyl-N-acrylamidopropyl-N-(2-carboxymethyl)-ammonium betaine, N,N-dimethyl-N-acrylamidopropyl-N-(3-sulfopropyl)-ammonium betaine, N,N-dimethyl-N-acrylamidopropyl-N-(2-carboxymethyl)-ammonium betaine, 2-(methylthio)ethyl methacryloyl-S-(sulfopropyl)-sulfonium betaine, 2-[(2-acryloylethyl)dimethylammonio]ethyl 2-methyl phosphate, 2-(acryloyloxyethyl)-2′-(trimethylammonium)ethyl phosphate, [(2-acryloylethyl)dimethylammonio]methyl phosphonic acid, 2-methacryloyloxyethyl phosphorylcholine (MPC), 2-[(3-acrylamidopropyl)dimethylammonio]ethyl 2′-isopropyl phosphate (AAPI), 1-vinyl-3-(3-sulfopropyl)imidazolium hydroxide, (2-acryloxyethyl)carboxymethyl methylsulfonium chloride, 1-(3-sulfopropyl)-2-vinylpyridinium betaine, N-(4-sulfobutyl)-N-methyl-N,N-diallylamine ammonium betaine (MDABS), N,N-diallyl-N-methyl-N-(2-sulfoethyl)ammonium betaine, and the like.

“Zwitterionic”, as defined herein, refers to a molecule containing both cationic and anionic substituents or electronic charges. Such molecules can have a net neutral overall charge, or can have a net positive or net negative overall electronic charge.

“Zwitterionic (co)polymers”, as defined herein, refer to (co)polymers derived from a zwitterionic monomer, a combination of anionic and cationic charged monomers or those derived from a zwitterionic monomer, including betaines, together with a component or components derived from other betaine monomers, ionic monomers, and non-ionic monomer(s), such as a hydrophobic and/or hydrophilic monomer. Suitable hydrophobic, hydrophilic, and betaine monomers are any of those known in the art. Representative zwitterionic co(polymers) include homopolymers, terpolymers, and (co)polymers. In polybetaines, all the polymer chains and segments within those chains are necessarily electrically neutral. As a result, polybetaines represent a subset of polyzwitterions, necessarily maintaining charge neutrality across all polymer chains and segments due to both anionic charge and cationic charge being introduced within the same monomer (see, for example, Lowe A. B., et al., Chemical Reviews 2002, Vol. 102, pp. 4177 4189, which is incorporated herein by reference).

“Zwitterionic monomer” means a polymerizable molecule containing cationic and anionic (thus, charged) functionalities in equal proportions, such that the molecule is typically, but not always, electronically neutral overall. Those monomers containing charges on the same monomer are termed “polybetaines.”

“Transition metal complex”, or “transition metal sol”, as defined herein, refers to a metal colloid solution/complex, wherein the metal is any of the metals comprising the d-block section of the Periodic Table of Elements that, as elements, have partly filled d shells in any of their commonly occurring oxidation states, constituting those elements in the first, second and third transition series, as defined by IUPAC.

“Living polymerization”, as used herein, refers to a process which proceeds by a mechanism whereby most chains continue to grow throughout the polymerization process, and where further addition of monomer results in continued polymerization. The molecular weight is controlled by the stoichiometry of the reaction.

“Radical leaving group” refers to a group attached by a bond that is capable of undergoing hemolytic scission during a reaction, thereby forming a radical.

“Stabilized” refers to the transition-metal-stabilized nanoparticles of the present invention, and refers to the ability of the colloids to resist aggregation for several weeks after preparation under an air atmosphere.

“Surface”, as used herein, refers to the exterior, external, upper, or outer boundary of an object or body, and is meant to include a plane or curved two-dimensional locus of points as the boundary of a three-dimensional region, e.g. a plane.

“GPC number average molecular weight”, (Mn) means a number average molecular weight, determined by Size Exclusion Chromatography (SEC).

“GPC weight average molecular weight”, (Mw) means a weight average molecular weight measured by utilizing gel permeation chromatography.

“Polydispersity” (Mw/Mn) means the value of the GPC weight average molecular weight divided by the GPC number average molecular weight.

Unless specified otherwise, alkyl groups referred to in this specification can be branched or unbranched and contain from 1 to 20 carbon atoms. Alkenyl groups can similarly be branched or unbranched, and contain from 2 to 20 carbon atoms. Saturated or unsaturated carbocyclic or heterocyclic rings can contain from 3 to 20 carbon atoms. Aromatic carbocyclic or heterocyclic rings can contain from 5 to 20 carbon atoms.

“Substituted”, as used herein, means that a group can be substituted with one or more groups that are independently selected from the group consisting of alkyl, aryl, epoxy, hydroxy, alkoxy, oxo, acyl, acyloxy, carboxy, carboxylate, sulfonic acid, sulfonate, alkoxy- or aryloxy-carbonyl, isocyanato, cyano, silyl, halo, dialkylamino, and amido. All substituents are chosen such that there is no substantial adverse interaction under the conditions of the experiments.

In describing certain polymers it should be understood that sometimes applicants are referring to the polymers by the monomers used to make them or the amounts of the monomers used to make them. While such a description may not include the specific nomenclature used to describe the final polymer or may not contain product-by-process terminology, any such reference to monomers and amounts should be interpreted to mean that the polymer is made from those monomers, unless the context indicates or implies otherwise.
As used herein, the terms “comprises,” “comprising,” “includes,” “including,” “has,” “having” or any other variation thereof, are intended to cover a non-exclusive inclusion. For example, a method, process, article, or apparatus that comprises a list of elements is not necessarily limited to only those elements but may include other elements not expressly listed or inherent to such method, process, article, or apparatus. Further, unless expressly stated to the contrary, “or” refers to an inclusive or and not to an exclusive or. For Example, a condition A or B is satisfied by any one of the following: A is true (or present) and B is false (or not present), A is false (or not present) and B is true (or present), and both A and B are true (or present).

Also, articles “a” or “an” are employed to describe elements and components of the invention. This is done merely for convenience and to give a general sense of the invention. This description should be read to include one or at least one and the singular also includes the plural unless it is obvious that it is meant otherwise.

### DETAILED DESCRIPTION OF THE PREFERRED EMBODIMENT(S)

The compositions of the present disclosure comprise suspended metal nanoparticle compositions, and methods of making the same, that are stabilized with decomposable stabilizers. When desired, the decomposable stabilizer can be decomposed thermally and/or with radiation, thereby enabling the composition to quickly precipitate conductive nanoparticles into a desired agglomerated shape; optionally thereafter, the agglomerate can be thermally annealed, preferably at a low temperature, for example, below about 110, 120, 130, 140, 150, 160, 170 or 180° C., and thus the compositions of the present disclosure can be used to form conductive features on high speed processes, such as, reel to reel embedding processes, ink jet printing, screen printing or the like. The optional low temperature thermal annealing is generally possible in accordance with the present invention, due to the efficient destabilization of the conductive nanoparticle, allowing metal surface to metal surface contact to form agglomerates which are easily sintered or annealed, generally at lower temperatures than might otherwise be expected.

The conductive nanoparticle compositions of the present disclosure comprise metal nanoparticles stabilized with a thermally decomposable stabilizer which has been found in some embodiments to also decompose, at least in part, using electromagnetic radiation, such as, ultraviolet or microwave radiation.

In further embodiments, conductive features are provided on a substrate by: providing a solution containing conductive nanoparticles with a stabilizer in accordance with the present disclosure; and liquid depositing the solution onto the substrate, wherein during the deposition or following the deposition of the solution onto the substrate, removing the stabilizer, by thermal treatment and/or by UV or microwave treatment, at a temperature below about 180, 170, 160, 150, 140 130, or 120° C. to form conductive features on the substrate.

Generally, the present disclosure describes an inexpensive and efficient process for preparing suspended nanoparticles having a substantially silver surface which can be taken out of suspension, quickly, accurately and efficiently, when desired, by the application of heat or electromagnetic radiation energy. The decomposable stabilizers of the present disclosure are (co)polymers prepared using the Reversible Addition-Fragmentation chain Transfer (“RAFT”) process. In one embodiment, the nanoparticles of this disclosure can be synthesized by the reaction of a silver complex such as a silver salt, colloid, or sol (e.g., silver nitrate), with thiocarbonylthio compounds in aqueous solution, either in the presence of a reducing agent or in the presence of high pH to drive a hydrolysis reaction. According to this aspect of the present disclosure, the methods described simultaneously converting the metal salt (or sol) into a silver conductive nanoparticle and the thiocarbonylthio group (of the decomposable stabilizer) to a thiol that readily connects to the silver surface, in one step, in situ.

In some embodiments, the thiocarbonylthio group does not need a reducing agent or require a hydrolysis reaction through the increase in pH, but rather, is able to displace the dispersing agent on the silver surface, where the dispersing agent is a weakly bonded surfactant (such as, citrate or other similar type weak acid salt) as wholly or partially dispersing the nanoparticle or nanoparticle precursor. A weakly bonded surfactant which originally provides at least some dispersion capability on the conductive nanoparticle is intended to mean a surfactant that is only weakly bonded to the silver surface, such as, by little, if any covalent bonding, and in addition having one or more of the following bonding mechanisms dipole-dipole interaction, hydrogen bonding, ion-dipole bonding, cation-pi bonding, pi stacking and London forces. In one embodiment, the thiocarbonylthio group is a trithiocarbonyl moiety that displaces a weak surfactant at the silver surface, without the need for increased pH (to cause hydrolysis) or without the need of a reducing agent.

Suitable polymerization monomers and comonomers of the present invention for creating the θ portion of the decomposable stabilizer of the present disclosure by RAFT synthesis include, but are not limited to, methyl methacrylate, ethyl acrylate, propyl methacrylate (all isomers), butyl methacrylate (all isomers), 2-ethylhexyl methacrylate, isobornyl methacrylate, methacrylic acid, benzyl methacrylate, phenyl methacrylate, methacrylonitrile, alpha-methylstyrene, methyl acrylate, ethyl acrylate, propyl acrylate (all isomers), butyl acrylate (all isomers), 2-ethylhexyl acrylate, isobornyl acrylate, acrylic acid, benzyl acrylate, phenyl acrylate, acrylonitrile, styrene, acrylates and styrenes selected from glycidyl methacrylate, 2-hydroxyethyl methacrylate, hydroxypropyl methacrylate (all isomers), hydroxybutyl methacrylate (all isomers), N,N-dimethylaminoethyl methacrylate, N,N-diethylaminoethyl methacrylate, triethyleneglycol methacrylate, itaconic anhydride, itaconic acid, glycidyl acrylate, 2-hydroxyethyl acrylate, hydroxypropyl acrylate (all isomers), hydroxybutyl acrylate (all isomers), N,N-dimethylaminoethyl acrylate, N,N-diethylaminoacrylate, triethyleneglycol acrylate, vinyl benzoic acid (all isomers), diethylaminostyrene (all isomers), alpha-methylvinyl benzoic acid (all isomers), diethylamino alpha-methylstyrene (all isomers), p-vinylbenzenesulfonic acid, p-vinylbenzene sulfonic sodium salt, trimethoxysilylpropyl methacrylate, triethoxysilylpropyl methacrylate, tributoxysilylpropyl methacrylate, dimethoxymethylsilylpropyl methacrylate, diethoxymethylsilylpropyl methacrylate, dibutoxymethylsilylpropyl methacrylate, diisopropyoxymethylsilylpropyl methacrylate, dimethoxysilylpropyl methacrylate, diethoxysilylpropyl methacrylate, dibutoxysilylpropyl methacrylate, diisopropoxysilylpropyl methacrylate, trimethoxysilylpropyl acrylate, triethoxysilylpropyl acrylate, tributoxysilylpropyl acrylate, dimethoxymethylsilylpropyl acrylate, diethoxymethylsilylpropyl acrylate, dibutoxymethylsilylpropyl acrylate, diisopropoxymethylsilylpropyl acrylate, dimethoxysilylpropyl acrylate, diethoxysilylpropyl acrylate, dibutoxysilylpropyl acrylate, diisopropoxysilylpropyl acrylate, vinyl acetate, vinyl butyrate, vinyl benzoate, vinyl chloride, vinyl fluoride, vinyl bromide, maleic anhydride, N-phenyl maleimide, N-butylmaleimide, N-vinylpyrrolidone, N-vinylcarbazole, betaines, sulfobetaines, carboxybetaines, phosphobetaines, butadiene, isoprene, chloroprene, ethylene, propylene, 1,5-hexadienes, 1,4-hexadienes, 1,3-butadienes, and 1,4-pentadienes.

Additional suitable polymerizable monomers and comonomers for the θ portion of the decomposable stabilizer of the present disclosure by RAFT synthesis include, but are not limited to, acrylic acids, alkylacrylates, acrylamides, methacrylic acids, maleic anhydride, alkylmethacrylates, methacrylamides, N-alkylacrylamides, N-alkylmethacrylamides, aminostyrene, dimethylaminomethystyrene, trimethylammonium ethyl methacrylate, trimethylammonium ethyl acrylate, dimethylamino propylacrylamide, trimethylammonium ethylacrylate, trimethylammonium ethyl methacrylate, trimethylammonium propyl acrylamide, dodecyl acrylate, octadecyl acrylate, and octadecyl methacrylate.

The free-radical polymerization initiators, or free radical source, of the present invention are chosen from the initiators conventionally used in radical polymerization, such as azo-compounds, hydrogen peroxides, redox systems, and reducing sugars. More specifically, the source of free radicals suitable for use with the present invention can also be any suitable method of generating free radicals, including but not limited to thermally induced homoytic scission of a suitable compound or compounds (s) [thermal initiators include peroxides, peroxyesters, and azo compounds], redox initiating systems, photochemical initiating systems, or high energy radiation such as electron beam, X-ray, microwave, or gamma-ray radiation UV. The initiating system is chosen such that under the reaction conditions, there is no substantial adverse interaction of the initiator, the initiator conditions, or the initiating radicals with the transfer agent under the conditions of the procedure. The initiator should also have the requisite solubility in the reaction medium or monomer mixture.

Thermal initiators are chosen to have an appropriate half-life at the temperature of polymerization. These initiators can include, but are not limited to, one or more of 2,2′-azobis(isobutyronitrile), 2,2′-azobis(2-cyano-2-butane), dimethyl 2,2′-azobisdimethylisobutyrate, 4,4′-azobis(4-cyanopentanoic acid), 1,1′-azobis(cyclohexanecarbonitrile), 2-(t-butylazo)-2-cyanopropane, 2,2′-azobis[2-methyl-N-(1,1)-bis(hydroxyethyl)]-propionamide, 2,2′-azobis(N,N′-dimethyleneisobutylamine), 2,2′-azobis[2-methyl-N-(2-hydroxyethyl)propionamide], 2,2′-azobis(isobutyramide) dihydrate, 2,2′-azobis(2,2,4-trimethylpentane), 2,2-azobis(2-methylpropane, t-butyl peroxyacetate, t-butyl peroxybenzoate, t-butyl peroxyoctoate, t-butyl peroxyneodecanoate, t-butylperoxy isobutyrate, t-amy peroxypivalate, t-butyl peroxypivalate, t-butyl peroxy2-ethylhexanoate, di-isopropyl peroxydicarbonate, dicyclohexyl peroxydicarbonate, dicumyl peroxide, dibenzoyl peroxide, dilauroyl peroxide, potassium peroxydisulfate, ammonium peroxydisulfate, di-t-butyl hyponitrite, and dicumyl hyponitrite.

Examples of hydrogen peroxides which may act as free-radical initiators according to the present disclosure include, but are not limited to, tert-butyl hydroperoxide, cumene hydroperoxide, tert-butyl peroxyacetate, lauroyl peroxide, tert-amyl peroxypivalate, tert-butyl peroxypivalate, dicumyl peroxide, hydrogen peroxide, Bz₂O₂ (dibenzoyl peroxide), potassium persulphate, and ammonium persulphate.

Redox initiator systems in accordance with the present disclosure are chosen to have the requisite solubility in the reaction medium, monomer mixture, or both, and have an appropriate rate of radical production under the conditions of the specific polymerization. Such initiating systems suitable for use with the present disclosure can include combinations of oxidants such as potassium peroxydisulfate, hydrogen peroxide, t-butyl hydroperoxide, and reductants such as iron (H), titanium (III), potassium thiosulfite, and potassium bisulfite. Other suitable initiating systems are described in Moad and Solomon, “The Chemistry of Free Radical Polymerization,” Pergamon, London, 1995; pp. 53 95, which is incorporated herein by reference.

Further examples of redox systems suitable for use with the present disclosure include, but are not limited to, mixtures of hydrogen peroxide or alkyl peroxide, peresters, percarbonates, and the like in combination with any one of the salts of iron, titaneous salts, zinc salts, zinc formaldehyde sulphoxylate, sodium salts, or sodium formaldehyde sulphoxylate.

The reactions of the present disclosure (e.g., polymerizations, surface modifications/immobilizations, and preparations of polymer-stabilized metal colloids or other appropriate surfaces, such as silicon, ceramic, metals, etc.) can be carried out in any suitable solvent or mixture thereof. Suitable solvents include, but are not limited to, water, alcohol (e.g. methanol, ethanol, n-propanol, isopropanol, butanol), tetrahydrofuran (THF), dimethyl sulfoxide (DMSO), dimethylformamide (DMF), acetone, acetonitrile, hexamethylphosphoramide (HMPA), hexane, cyclohexane, benzene, toluene, methylene chloride, ether (e.g. diethyl ether, butyl ether or methyl tert-butyl ether), methyl ethyl ketone (MEK), chloroform, ethyl acetate, and mixtures thereof. Preferably, the solvents include water, mixtures of water, or mixtures of water and water-miscible organic solvents, such as DMF. In one embodiment, water is the solvent.

For heterogeneous polymerization, it is desirable to choose a CTA which has appropriate solubility characteristics. For example, for aqueous emulsion polymerization, the CTA should preferably partition in favor of the organic (monomer) phase and yet have sufficient aqueous solubility that it is able to distribute between the monomer droplet phase and the polymerization locus.

The chain transfer reagents (CTAs) of the present disclosure are compounds, such as dithioester compounds, water-soluble dithioester compounds, disulphides, xanthate disulphides, thiocarbonylthio compounds, and dithiocarbamates which react with either the primary radical or a propagating polymer chain, thereby forming a new CTA and eliminating the R radical, thereby reinitiating polymerization. The CTAs of the present invention are either commercially available, such as carboxymethyl dithiobenzoate, or readily synthesized using known procedures. Examples of CTAs suitable for use in the present invention are cumyl dithiobenzoate, DTBA (4-cyanopentanoic acid dithiobenzoate), BDB (benzyl dithiobenzoate), CDB (isopropyl cumyl dithiobenzoate), TBP (N,N-dimethyl-s-thiobenzoylthiopropionamide), TBA (N,N-dimethyl-s-thiobenzoylthioacetamide, trithiocarbonates, dithiocarbamates, (phosphoryl)dithioformates and (thiophosphoryl)dithioformates, bis(thioacyl)disulfides, xanthates, dithiocarbonate groups used in MADIX (Macromolecular Design via Interchange of Xanthate) which are either commercially available, synthesized according to well-established organic synthesis routes, or synthesized as previously described in U.S. Pat. No. 6,153,705, which is hereby incorporated by reference, and CTPNa (sodium 4-cyanopentanoic acid dithiobenzoate) and related compounds, such as those described in U.S. Pat. No. 6,153,705, and PCT International Application WO 9801478 A1, which are herein incorporated by reference.

The choice of polymerization conditions is also important. The reaction temperature should generally be chosen such that it will influence rate in the desired manner. For example, higher temperatures will typically increase the rate of fragmentation. Conditions should be chosen such that the number of chains formed from initiator-derived radicals is minimized to an extent consistent with obtaining an acceptable rate of polymerization. The polymerization process of the present invention is performed under conditions typical of conventional free-radical polymerization. Polymerization employing the CTAs described above are suitably carried out with temperatures in the range of −20° C. to 160° C., preferably in the range of 10° C. to 150° C., and most preferably at temperatures in the range of 10° C. to 80° C.

The pH of a polymerization conducted in an aqueous or semi-aqueous solution can be varied depending upon the conditions and the reactants. Generally, however, the pH is selected so that the selected dithioester is stable and grafting of the polymer can occur. Typically, the pH is from about 0 to about 9, preferably from about 1 to about 7, and more preferably from about 2 to about 7. The pH can be adjusted using any of the means known in the art.

Representative transition metal sols preferred for use in this invention include, but are not limited to, complexes formed from silver (Ag) and associated salts (e.g., AgNO₃).

Examples of azo-compounds which may act as free-radical initiators according to the present invention include, but are not limited to, AlBMe (2,2′-azobis(methyl isobutyrate), AlBN (2,2′-azobis(2-cyanopropane), ACP (4,4′-azobis(4-cyanopentanoic acid), AB (2,2′-azobis(2-methylpropane), 2,2′-azobis(isobutyronitrile), 2,2′-azobis(2-butanenitrile), 2,2′-azobis[2-methyl-N-(1,1)-bis(hydroxymethyl)-2-hydroxyethyl]propionami-de, and 2,2′-azobis(2-amidinopropane)dichloride.

Suitable anionic (co)polymers include PAMPS (poly(sodium 2-acrylamido-2-methylpropanesulfonate), PAMBA, and other suitable anionic (co)polymers known in the art. Preparation of such anionic (co)polymers is known in the art, and is herein incorporated by reference (Sumerlin, B., et al. Macromolecules 2001, 34, 6561).

Suitable cationic (co)polymers include PVBTAC (poly(4-vinylbenzyl)trimethylammonium chloride), and other related cationic (co)polymers which are commercially available or available through known synthetic routes.

Suitable nonionic, or neutral (co)polymers include representative (co)polymers including, but not limited to, PDMA (poly(N,N-dimethylacrylamide), and other related neutral (co)polymers which are commercially available or available through known synthetic procedures.

Suitable zwitterionic (co)polymers include PMAEDAPS-b-PDMA (poly(3-[2-N-methylacrylamido)-ethyl dimethyl ammonio propanesulfonate-block-N,N-dimethylacrylamide), and other zwitterionic (co)polymers commercially available or available through known synthetic procedures. Preferably, the zwitterionic (co)polymer useful in the present invention comprises a component derived from a zwitterionic monomer (betaine) together with a component or components derived from a hydrophobic or hydrophilic monomer or a mixture of components derived from hydrophobic and hydrophilic monomers.

Suitable betaines include, but are not limited to, ammonium carboxylates, ammonium phosphates, and ammonium sulphonates. Particular zwitterionic monomers which can be utilized are N-(3-sulphopropyl)-N-methylacryloxyethyl-N,N-dimethyl ammonium betaine, and N-(3-sulphopropyl)-N-allyl-N,N-dimethyl ammonium betaine.

The dithioester-end capped (co)polymers used in the present disclosure can be synthesized using a controlled synthesis in aqueous media, employing any number of chain-transfer agents, most preferably a dithiobenzoate or related compound as described above, and a free radical initiator. The RAFT processes of the present invention can be carried out in aqueous media, in bulk, solution, emulsion, microemulsion, mini-emulsion, inverse emulsion, inverse microemulsion, or suspension, in either a batch, semi-batch, continuous, or feed mode. The initiators are the free-radical initiators described above, with the azo-initiators being preferred. (Co)polymer molecular masses were controlled by varying the monomer-to-CTA molar ratio. The CTA-to-initiator molar ratio is at least one thousand-to-one (1000:1) to one to one 1:1. Solution pH can be adjusted as necessary to ensure complete ionization of the monomers, depending on the charge.

Turning now to an exemplary process according to the present disclosure, the synthesis begins with the preparation of an aqueous solution of metal salt or sol, for example in one embodiment, the amount of metal salt or sol can be about 0.01 wt %. Such a metal colloidal solution can then be preferentially added to a container which has been charged with a dithioester end-capped (co)polymer, as described above. The mixture can then be mixed, in order to ensure homogeneity, and an aqueous solution of reducing agent (1.0 M) can then be added slowly. The mixture can then be stirred, under ambient (about 1 atmosphere) pressure, at room temperature for a time up to about 48 hours. The resultant product can be recovered by centrifugation, or any other suitable means of removing the reaction solution from the product of the invention.

According to the present disclosure, the reducing agent can be a boron hydride compound and/or aluminum hydride compound, or a hydrazine compound. More specifically, the reducing agent can include, but is not limited to, alkali metal borohydrides, alkali earth metal borohydrides, alkali metal aluminum hydrides, dialkylaluminum hydrides and diborane, among others. These may be used singly or two or more of them may be used in a suitable combination. The salt-forming alkali metal in the reducing agent is, for example, sodium, potassium, or lithium and the alkaline earth metal is calcium or magnesium. In consideration of the case of ease of handling and from other viewpoints, alkali metal borohydrides are preferred, and sodium borohydride can be particularly preferred.

Other preferred reducing agents suitable for use with the present disclosure can include, but are not limited to: borohydrides such as lithium borohydride, potassium borohydride, calcium borohydride, magnesium borohydride, zinc borohydride, aluminum borohydride, lithium triethylborohydride [Super Hydride], lithium dimesitylborohydride, lithium trisiamylborohydride, and sodium cyanoborohydride; lithium aluminum hydride, alane (AlH.sub.3), alane-N,N-dimethylethylamine complex, L-Selectride™ (lithium tri-sec-butylborohydride), LS-Selectride™ (lithium trisiamylborohydride), Red-Al® or Vitride® (sodium bis(2-methoxyethoxy)aluminum hydride; alkoxyaluminum hydrides such as lithium diethoxyaluminum hydride, lithium trimethoxyaluminum hydride, lithium triethoxyaluminum hydride, lithium tri-t-butyoxyaluminum hydride, and lithium ethoxyaluminum hydride; alkoxy- and alkylborohydrides, such as sodium trimethoxyborohydride and sodium triisopropoxyborohydride; boranes, such as diborane, 9-BBN, and Alpine Borane®; aluminum hydride, and diisobutylaluminum hydride (Dibal); hydrazine, and the like. Together with such a reducing agent, a suitable activator known in the art may be combined and used for improving the reducing power of the reducing agent. The reducing agent can be used in solid form, in solution with a suitable solvent, or can be attached to an inert support, such as polystyrene, alumina, and the like. The reducing agent to be used should be mostly soluble in a solvent, particularly in water (e.g., NaBH₄, LiBH₄, or hydrazine), or alternatively in an organic solvent which is miscible with water. For example, it is envisioned that that the process of the present disclosure can be done using an organic solvent such as tetrahydrofuran (THF) or a THF-water mixture with LiBHEt₃ (Super Hydride® as the reducing agent.

The amount of the reducing agent is not particularly restricted, but it is preferred to be in an amount such that reducing agent is provided in an amount not less than the stoichiometric amount relative to the amount of the thiocarbonythio compound. For example, the reduction can be effected using sodium borohydride in an amount of not less than 0.5 mole, preferably not less than 1.0 mole, per mole of the thiocarbonylthio compound. From the economic viewpoint, the amount of reducing agent is not more than 10.0 moles, and preferably not more than 2.0 moles per mole of the thiocarbonylthio compound.

In the instance of silver included in the present invention, and hence included within the present invention, the addition of the reducing agent results in the reduction of the dithioester end group of the polymer, resulting in the corresponding thiol functionality on the (co)polymer with the simultaneous reduction of the silver ion to the elemental state.

In addition to the above embodiments, the silver nanoparticles or surfaces stabilized or modified by (co)polymers synthesized using RAFT can be further modified at their terminal functional end group using a variety of reaction conditions, such as reagents, time, and temperature.

Further embodiments of the present invention include RAFT polymerizations of polymers from a surface, such as from a nanoparticles, film, or wafer. In such an instance, either the free radical initiator or the CTA can be attached to the nanoparticle or surface by any of numerous reactions known in the art. Following such attachment, the RAFT polymerizations can be carried out in a variety of solvents, preferably water or water-solvent emulsion.

The present disclosure relates also to production processes and to substrates provided with conductive metallizations made by said production process. Said production process includes the steps:
(1) providing a substrate,
(2) applying the conductive composition of the invention on the substrate, and
(3) subjecting the conductive composition applied in step (2) to photonic sintering to form the conductive metallization.
   For embodiments where the decomposable stabilizer comprises acid cleavable groups by a catalytically active process, the photonic sintering can be done with the aid of a photo acid generator as illustrated in Table 1 below:

TABLE 1

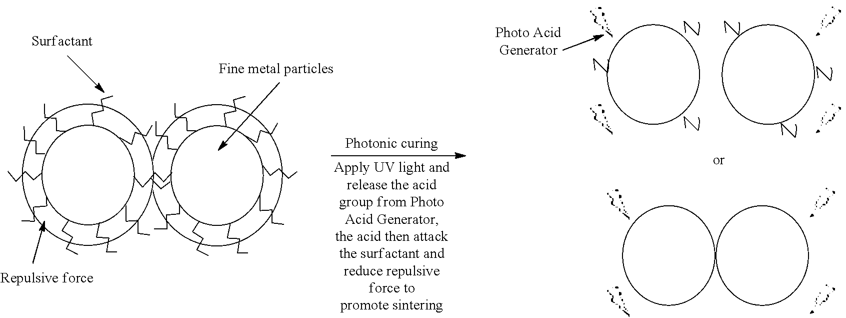

The “surfactant” indicated in Table 1 is intended to mean the thermally decomposable stabilizer of the present disclosure or alternatively, can mean a secondary surfactant in addition to the thermally decomposable stabilizer, wherein the heat or ultra-violet radiation of the photonic curing step will also destabilize the thermally decomposable stabilizer in addition to or separate from the presence of the photo acid. The “fine metal particles” indicated in Table 1 is intended to mean nanoparticles comprising silver, at least at the nanoparticle surface.

In an alternative embodiment, photo curing can directly degrade the surfactant (without the use of a photo acid generator), and the surfactant can be a secondary surfactant and/or the thermally decomposable stabilizer of the present disclosure. This embodiment is illustrated in Table 2.

TABLE 2

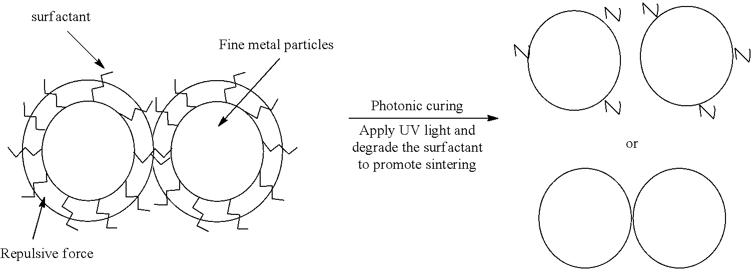

In step (1) of the process of the invention a substrate is provided. The substrate may be comprised of one or more than one material. The term “material” used herein in this context refers primarily to the bulk material or the bulk materials the substrate is comprised of. However, if the substrate is comprised of more than one material, the term “material” shall no be misunderstood to exclude materials present as a layer. Rather, substrates comprised of more than one material include substrates comprised of more than one bulk material without any thin layers as well as substrates comprised of one or more than one bulk material and provided with one or more than one thin layer. Examples of said layers include dielectric (electrically insulating) layers and active layers.

Examples of dielectric layers include layers of inorganic dielectric materials like silicon dioxide, zirconia-based materials, alumina, silicon nitride, aluminum nitride and hafnium oxide; and organic dielectric materials, e.g. fluorinated polymers like PTFE, polyesters and polyimides. The dielectric layer can be solid or porous.

The term “active layer” is used in the description and the claims. It shall mean a layer selected from the group including photoactive layers, light-emissive layers, semiconductive layers and non-metallic conductive layers. In an embodiment, it shall mean layers selected from the group consisting of photoactive layers, light-emissive layers, semiconductive layers and non-metallic conductive layers.

For the purpose of the present disclosure, the term “photoactive” used herein shall refer to the property of converting radiant energy (e.g., light) into electric energy.

Examples of photoactive layers include layers based on or including materials like copper indium gallium diselenide, cadmium telluride, cadmium sulphide, copper zinc tin sulphide, amorphous silicon, organic photoactive compounds or dye-sensitized photoactive compositions.

Examples of light-emissive layers include layers based on or including materials like poly(p-phenylene vinylene), tris(8-hydroxyquinolinato)aluminum or polyfluorene (derivatives).

Examples of semiconductive layers include layers based on or including materials like copper indium gallium diselenide, cadmium telluride, cadmium sulphide, copper zinc tin sulphide, amorphous silicon or organic semiconductive compounds.

Examples of non-metallic conductive layers include layers based on or including organic conductive materials like polyaniline, PEDOT:PSS (poly-3,4-ethylenedioxythiophene polystyrenesulfonate), polythiophene or polydiacetylene; or based on or including transparent conductive materials like indium tin oxide (ITO), aluminum-doped zinc oxide, fluorine-doped tin oxide, graphene or carbon nanotubes.

In an embodiment, the substrate is a temperature-sensitive substrate. This means that the material or one or more of the materials the substrate is comprised of are temperature-sensitive. For the avoidance of doubt, this includes such cases, where the substrate includes at least one of the aforementioned layers wherein the layer or one, more or all layers are temperature-sensitive.

The term “temperature-sensitive” as opposed to “temperature-resistant” is used herein with reference to a substrate, a substrate material (=the or one of the bulk materials a substrate is comprised of) or a layer of a substrate and its behavior when exposed to heat. Hence, “temperature-sensitive” is used with reference to a substrate, a substrate material or a layer of a substrate which does not withstand a high object peak temperature of >130° C. or, in other words, which undergoes an unwanted chemical and/or physical alteration at a high object peak temperature of >130° C. Examples of such unwanted alteration phenomena include degradation, decomposition, chemical conversion, oxidation, phase transition, melting, change of structure, deformation and combinations thereof. Object peak temperatures of >130° C. occur for example during a conventional drying or firing process as is typical y used in the manufacture of metallizations applied from metal pastes containing conventional polymeric resin binders or glass binders.

Accordingly, the term “temperature-resistant” is used herein with reference to a substrate, a substrate material or a layer of a substrate which withstands an object peak temperature of >130° C.

A first group of examples of substrate materials includes organic polymers. Organic polymers may be temperature-sensitive. Examples of suitable organic polymer materials include PET (polyethylene terephthalate), PEN (polyethylene napthalate), PP (polypropylene), PC (polycarbonate) and polyimide.

A second group of examples of substrate materials includes materials other than an organic polymer, in particular, inorganic non-metallic materials and metals. Inorganic non-metallic materials and metals are typically temperature-resistant. Examples of inorganic non-metallic materials include inorganic semiconductor materials like monocrystalline silicon, polycrystalline silicon, silicon carbide; and inorganic dielectric materials like glass, quartz, zirconia-based materials, alumina, silicon nitride and aluminum nitride. Examples of metals include aluminum, copper and steel.

The substrates may take various forms, examples of which include the form of a film, the form of a foil, the form of a sheet, the form of a panel and the form of a wafer.

In step (2) of the process of the invention the conductive composition is applied on the substrate. In case the substrate is provided with at least one of the aforementioned layers, the conductive composition may be applied on such layer. The conductive composition may be applied to a dry film thickness of, for example, 0.1 to 100 μm. The method of conductive composition application may be printing, for example, flexographic printing, gravure printing, ink-jet printing, offset printing, screen printing, nozzle/extrusion printing, aerosol jet printing, or it may be pen-writing. The variety of application methods enables the conductive composition to be applied to cover the entire surface or only one or more portions of the substrate. It is possible for example to apply the conductive composition in a pattern, wherein the pattern may include fine structures like dots or thin lines with a dry line width as low as, for example 50 or 100 nanometers.

After its application on the substrate the conductive composition may be dried in an extra process step prior to performing step (3) or it may directly (i.e. without deliberate delay and without undergoing an especially designed drying step) be subject to the photonic sintering step (3). Such extra drying step will typically mean mild drying conditions at a low object peak temperature in the range of 50 to ≦130° C.

The term “object peak temperature” used herein in the context of said optional drying means the substrate peak temperature reached during drying of a conductive metallization applied from the conductive composition of the invention onto the substrate.

The primary target of said optional drying is the removal of solvent; however, it may also support the densification of the metallization matrix. The optional drying may be performed, for example, for a period of 1 to 60 minutes at an object peak temperature in the range of 50 to ≦130° C., or, in an embodiment, 80 to ≦130° C. The skilled person will select the object peak temperature considering the thermal stability of the ethyl cellulose resin and of the substrate provided in step (1) and the type of diluent included in the conductive composition of the invention.

The optional drying can be carried out making use of, for example, a belt, rotary or stationary dryer, or a box oven. The heat may be applied by convection and/or making use of IR (infrared) radiation. The drying may be supported by air blowing.

Alternatively, the optional drying may be performed using a method which induces a higher local temperature in the metallization than in the substrate as a whole, i.e. in such case the object peak temperature of the substrate may be as low as room temperature during drying. Examples of such drying methods include photonic heating (heating via absorption of high-intensity light), microwave heating and inductive heating.

In step (3) of the process of the invention the conductive metal composition applied in step (2) and optionally dried in the aforementioned extra drying step is subjected to photonic sintering to form the conductive metallization.

Photonic sintering which may also be referred to as photonic curing uses light, or, to be more precise, high-intensity light to provide high-temperature sintering. The light has a wavelength in the range of, for example, 240 to 1000 nm. Typically, flash lamps are used to provide the source of light and are operated with a short on time of high power and a duty cycle ranging from a few hertz to tens of hertz. Each individual flashlight pulse may have a duration in the range of, for example, 100 to 2000 microseconds and an intensity in the range of, for example, 30 to 2000 Joules. The flashlight pulse duration may be adjustable in increments of, for example, 5 microseconds. The dose of each individual flashlight pulse may be in the range of, for example, 4 to 15 Joule/cm².

The entire photonic sintering step (3) is brief and it includes only a small number of flashlight pulses, for example, up to 5 flashlight pulses, or, in an embodiment, 1 or 2 flashlight pulses. It has been found that the conductive composition of the invention, unlike known prior art conductive compositions, enables the photonic sintering step (3) to be performed in an unusually short period of time of, for example, ≦1 second, e.g. 0.1 to 1 seconds, or, in an embodiment, ≦0.15 seconds, e.g. 0.1 to 0.15 seconds; i.e. the entire photonic sintering step (3) commencing with the first flashlight pulse and ending with the last flashlight pulse can be as short as, for example, ≦ 1 second, e.g. 0.1 to 1 seconds, or, in an embodiment, ≦0.15 seconds, e.g. 0.1 to 0.15 seconds.

The conductive films created in accordance with the present disclosure can be used as donor substrates for photovoltaic applications, and as such, can be used in association with acceptor substrates.

The metallized substrate obtained after conclusion of step (3) of the process of the invention may represent an electronic device, for example, a printed electronic device. However, it is also possible that it forms only a part of or an intermediate in the production of an electronic device. Examples of said electronic devices include RFID (radio frequency identification) devices; PV (photovoltaic) or OPV (organic photovoltaic) devices, in particular solar cells; light-emissive devices, for example, displays, LEDs (light emitting diodes), OLEDs (organic light emitting diodes); smart packaging devices; and touchscreen devices. In case the metallized substrate forms only said part or intermediate it is further processed. One example of said further processing may be encapsulation of the metallized substrate to protect it from environmental impact. Another example of said further processing may be providing the metallization with one or more of the aforementioned dielectric or active layers, wherein in case of an active layer direct or indirect electrical contact is made between metallization and active layer. A still further example of said further processing is electroplating or light-induced electroplating of the metallization which then serves as a seed metallization.

The following examples are included to demonstrate alternative embodiments of the invention. It should be appreciated by those of skill in the art that the techniques disclosed in the examples which follow represent techniques discovered by the inventors to function well in the practice of the invention, and thus can be considered to constitute preferred modes for its practice. However, those of skill in the art should, in light of the present disclosure, appreciate that many changes can be made in the specific embodiments which are disclosed and still obtain a like or similar result without departing from the spirit and scope of the invention.

Preparation of Stearylmethacrylate/methyl methacrylate Trithiocarbonate

A 4-neck flask fitted with addition funnel, condenser, and nitrogen gas inlet, thermocouple+initiator feed line, and an overhead stirrer assembly was charged with trithiocarbonate RAFT agent C₁₂H₂₅SC(S)SC(CH₃)(CN)CH₂CH₂CO₂CH₃ (4.40 g=10.55 mmol) and MEK (180 mL). MMA (166 g) and stearyl methacrylate (34.0 g) were added to the vessel at room temperature. The reactor was purged with nitrogen for 20 min and the temperature was increased to 73° C. V-601 solution initiator (420 mg, 1.82 mmol, 6.6 mL) was stage-fed over 21 hr. Heating was continued for 22 hr.

NMR (CDCl₃) showed final MMA conversion was 98.5%.

Reaction mixture was diluted with MEK (70 mL), and cooled to room temperature. The polymer solution was added slowly to methanol (1.50 at 5° C., and stirred for ca. 45 min after addition was complete. The liquid phase was removed. Methanol (1.5 L) was added and the mixture was stirred for 1 hr. Filtration and drying gave 196.8 g of solid.

NMR(CDCl₃): 3.9 (m, a=200, 100/H, stearylMA), 3.67-3.5 (m, main peak at 3.58 (a=5489.2, 1829.7/H), consistent with stearylMA/MMA=5.2/94.8 (mol %), 15.7/84.3 wt %.

SEC: data (vs. PMMA standards): Mw=26502; Mn=23932; Mz=29219, MP=26493; PD=1.11.

### Preparation of StearylMA/MMA-b-DEAEMA-TTC

A 4-neck flask fitted with addition funnel, condenser, and nitrogen gas inlet, thermocouple+initiator feed line, and an overhead stirrer assembly was charged with stearylMA/MMA-ttc (93.5 g) and MEK (150 mL). V-601 solution was prepared for syringe pump feeding using 475 mg/10.00 mL, 0.207 mmol/mL, using MEK as solvent. The reactor was purged with nitrogen for 20 min. DEAEMA monomer (46.8 g, 0.253 mol) was charged to a syringe. 5.0 mL of DEAEMA was added to the vessel, and the temperature was increased to 73° C. V-601 initiator 289 mg, 1.26 mmol) was stage-fed over 16 hr. Remaining DEAEMA monomer was fed over a 4 hr period. Heating was continued for 19 hr.

Reaction mixture was diluted with MEK (150 mL), stirred until uniform and cooled to room temperature. Reaction mixture was added to 3 L hexane. After stirring, the liquid phase was removed and another 2 L portion of hexane was added and stirring was continued for 1 hr. Filtration and drying afforded 100 g of solid, 96.5 g. Liquid phase processing gave an additional 30 g solid with identical SEC and NMR characteristics.

NMR(CDCl₃): 4.20-3.90 (m, a=65.73; combination of OCH₂ groups, 3.58 (OCH₃ signal, a=300), 2.72 and 2.60 (m's, a=173.9, NCH₂ groups). Consistent with stearylMA/MMA/DEAEMA=4.0/73.7/22.2 mol %, or 10.5/57.4/32.0 wt %.

SEC (triple detection in HFIP) showed Mw=38.5 kDa, PDI=1.04.

All of the processes disclosed and claimed herein can be made and executed without undue experimentation in light of the present disclosure. While the compositions and methods of this invention have been described in terms of preferred embodiments, it will be apparent to those of skill in the art that variations may be applied to the processes and in the steps or in the sequence of steps of the methods described herein without departing from the concept, spirit and scope of the invention. More specifically, it will be apparent that certain agents which are chemically related may be substituted for the agents described herein while the same or similar results would be achieved. All such similar substitutes and modifications apparent to those skilled in the art are deemed to be within the spirit, scope and concept of the invention.

What is claimed is:

1. A composition for high speed printing of conductive materials for electronic circuitry type applications, consisting essentially of:
a dispersion having:
A. a continuous phase; and
B. a discontinuous phase comprising a plurality of nanoparticles stabilized with a thermally decomposable stabilizer, wherein:
a. the nanoparticles comprise: i. at least 20 weight percent silver at the particle surface; ii. an aspect ratio of from 1-3:1; and iii. a particle size of 1 to 100 nanometers;
b. the thermally decomposable stabilizer is an Φ-b-θ-Y block co-polymer or oligomer by Reversible Addition-Fragmentation chain Transfer (RAFT) synthesis, the block copolymer or oligomer being applied to the nanoparticles or a nanoparticle precursor in the presence of: i. a reducing agent sufficient to cause a reduction within Y; ii. an increase in pH sufficient to cause hydrolysis within Y; iii. a weak surfactant on the nanoparticle or nanoparticle precursor; or iv. a combination of two or more of i., ii, and iii.,
wherein,
I. Φ is a polymeric block or series of polymeric blocks that swell and suspend in the continuous phase, Φ having a weight average molecular weight in a range from 1000 to 150,000;
II. b indicates a covalent bond between Φ and θ;
III. θ comprises at least one acrylate or methacrylate moiety having a functional group from the group consisting of: tertiary amine, amide, heterocyclic amine, pyridine, electron rich aromatics and combinations thereof, where θ is from 5 weight percent to 20 weight percent of the thermally decomposable stabilizer;
IV. Y is a dithioester, a xanthate, a dithiocarbamate, a trithiocarbonate or combinations thereof; and
V. upon heating the discontinuous phase to a temperature above 100° C., for a time within the range of 0.01 to 5 minutes, sufficient bond cleavage occurs within Y or between Y and θ to cause at least 20 weight percent of the nanoparticles to fall out of suspension and agglomerate to create an nanoparticle agglomerate with a resistance of less than 100 Ohms.

2. A composition in accordance with claim 1, wherein upon heating the discontinuous phase to a temperature of above 110° C., for a time within the range of 0.01 to 5 minutes, sufficient bond cleavage occurs within Y or between Y and θ to cause at least 50 weight percent of the nanoparticles to fall out of suspension and agglomerate to create an nanoparticle agglomerate with a resistance of less than 100 Ohms.

3. A composition in accordance with claim 1, wherein upon heating the discontinuous phase to a temperature of above 120° C., for a time within the range of 0.01 to 5 minutes, sufficient bond cleavage occurs within Y or between Y and θ to cause at least 50 weight percent of the nanoparticles to fall out of suspension and agglomerate to create an nanoparticle agglomerate with a resistance of less than 100 Ohms.

4. A composition in accordance with claim 1, wherein upon heating the discontinuous phase to a temperature of above 130° C., for a time within the range of 0.01 to 5 minutes, sufficient bond cleavage occurs within Y or between Y and θ to cause at least 50 weight percent of the nanoparticles to fall out of suspension and agglomerate to create an nanoparticle agglomerate with a resistance of less than 100 Ohms.

5. A composition in accordance with claim 1, wherein upon heating the discontinuous phase to a temperature of above 140° C., for a time within the range of 0.01 to 5 minutes, sufficient bond cleavage occurs within Y or between Y and θ to cause at least 50 weight percent of the nanoparticles to fall out of suspension and agglomerate to create an nanoparticle agglomerate with a resistance of less than 100 Ohms.

6. A composition in accordance with claim 1, wherein upon heating the discontinuous phase to a temperature of above 150° C., for a time within the range of 0.01 to 5 minutes, sufficient bond cleavage occurs within Y or between Y and θ to cause at least 50 weight percent of the nanoparticles to fall out of suspension and agglomerate to create an nanoparticle agglomerate with a resistance of less than 100 Ohms.

7. A composition in accordance with claim 1, wherein the continuous phase comprises a solvent from the group consisting of: water, an organic solvent having one or more functional groups from the group consisting of hydroxyl (—OH), amide, ether, ester, sulfone, and combinations thereof.

8. A composition in accordance with claim 1, wherein the continuous phase comprises an alcohol functionality, optionally further comprising water, and the thermally decomposable stabilizer is in a range of 0.1 to 10 weight percent of the total weight of the discontinuous phase.

9. A composition in accordance with claim 3, wherein the continuous phase is less than 80 wt % of the total weight of the continuous phase and discontinuous phase.

10. A composition in accordance with claim 1 further comprising a surfactant to lower the interfacial tension between the continuous phase and discontinuous phase.

11. A method of printing a conductive feature, comprising:
a. depositing the composition of claim 1 onto a substrate;
b. heating the discontinuous phase of the composition of claim 1 to a temperature in a range of from 100° C. to 150° C. for a period of time in a range of 0.1 to 30 minutes to cause at least 50 wt % of the nanoparticles to fall out of suspension to form a nanoparticle agglomerate;
c. removing at east a portion of the continuous phase using thermal energy; and
d. optionally, heating the nanoparticle agglomerate to further sinter the nanoparticle agglomerate, thereby lowering the resistivity of the nanoparticle agglomerate.

12. A composition in accordance with claim 1, wherein the thermally decomposable stabilizer comprises or is derived from stearyl-MA/MMA-b-DEAEMA-ttc, where:
i. stearyl-MA is 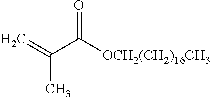
ii. MMA is methylmethacrylate;
iii. MA is methacrylate;
iv. stearyl is CH₃(CH₂)₁₆CH₂; and
v. ttc is trithiocarbonate; and
vi. DEAE is diethyl amino ethyl

13. A composition in accordance with claim 1 wherein the thermally decomposable stabilizer comprises or is derived from stearyl-MA/MMA-b-DMAEMA-ttc, where:
i. stearyl-MA is 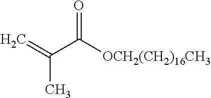
ii. MMA is methylmethacrylate;
iii. MA is methacrylate;
iv. stearyl is CH3(CH2)16CH2; and
V. ttc is trithiocarbonate; and
vi. DMAE is dimethyl amino ethyl.

14. A composition in accordance with claim 12 wherein the thermally decomposable stabilizer comprises or is derived from AA-b-PEA-ttc, where:
i. AA is acrylic acid;
ii. PEA is penoxyethylacrylate;
iii. MA is methacrylate; and
iv. ttc is trithiocarbonate.

15. A composition in accordance with claim 1 wherein the polymeric block or series of polymeric blocks is at least partially soluble in the continuous phase.
